(19) United States
(12) Patent Application Publication
(10) Pub. No.: US 2024/0164071 A1
(43) Pub. Date: May 16, 2024

(54) POWER ELECTRONIC SYSTEMS PACKAGED USING COMMON HEAT SINK AND ENCLOSURE

(71) Applicant: Caterpillar, Inc., Peoria, IL (US)

(72) Inventors: Michael R. Garrabrant, Dunlap, IL (US); Luke A. Ketcham, Peoria, IL (US); Yingying Kuai, Dunlap, IL (US); Matthew Ernest Williams, Peoria, IL (US); Suudharshana Madhavann, Dallas, TX (US)

(73) Assignee: Caterpillar Inc., Peoria, IL (US)

(21) Appl. No.: 17/984,505

(22) Filed: Nov. 10, 2022

(51) Int. Cl. H05K 7/20; H02M 3/10; H05K 1/02; H05K 7/14

(52) U.S. Cl. CPC H05K 7/20927; H02M 3/10; H05K 1/0203; H05K 7/1432; H05K 7/209

(57) ABSTRACT

An assembly for two (or more) DC/DC converters located in a common enclosure, where the DC/DC converters share a heat sink assembly, such as a shared dual-sided heat sink assembly. The techniques efficiently package the components of the DC/DC converters within a common enclosure and simplify the cooling lines routed to those components.

### TECHNICAL FIELD

This document relates generally to power electronic systems and, more particularly, to the packaging of a power electronic system.

### BACKGROUND

In response to fuel efficiency concerns and desired performance characteristics, an emphasis has been placed on using electrical power to operate various components associated with a vehicle. Battery powered machines provide many advantages over combustion engine powered machines. One advantage is that battery powered machines do not emit combustion byproducts. This advantage is particularly useful in underground mining environments. A combustion-engine underground-mining machine may often need to be paired with ventilation systems that provide fresh air to the machine and that carry away the combustion exhaust aboveground.

Battery powered machines include one or more power storage devices (e.g., batteries) to receive and store electrical power. To transfer power to components of the battery powered machine, the electrical system architecture of the battery powered machine includes a DC/DC converter configured to receive DC power at a first voltage and convert the DC power at the first voltage to DC power at a second voltage.

CN113890273A discloses a double-bridge assembly. The double-bridge assembly comprises a mounting shell, a first motor, a second motor, a first controller and a second controller, where the first motor, the second motor, the first controller and the second controller are all mounted in the mounting shell. The assembly further includes a first cooling water channel and a second cooling water channel, where the first cooling water channel is arranged on the mounting shell and used for exchanging heat with the first controller and the first motor, and the second cooling water channel is arranged on the mounting shell and used for exchanging heat with the second controller and the second motor. The assembly further includes an oil cooler, where an oil cooling water channel is integrated in the oil cooler, the first cooling water channel and the second cooling water channel are both communicated with the oil cooling water channel, and the oil cooler is provided with a water outlet nozzle communicated with the oil cooling water channel.

### SUMMARY

This disclosure describes, among other things, an assembly for two (or more) DC/DC converters located in a common enclosure, where the DC/DC converters share a heat sink assembly, such as a shared dual-sided heat sink assembly. The techniques of this disclosure efficiently package the components of the DC/DC converters within a common enclosure and simplify the cooling lines routed to those components.

In an aspect, this disclosure is directed to an assembly for two DC/DC converters located in a shared enclosure, the assembly comprising: a first DC/DC converter including: a first power electronic module configured to receive a first DC input voltage and generate a first voltage; a second power electronic module configured to generate a second voltage; and a first transformer electrically coupled between the first power electronic module and the second power electronic module; a second DC/DC converter including: a third power electronic module configured to receive a second DC input voltage and generate a third voltage; a fourth power electronic module configured to generate a fourth voltage; and a second transformer electrically coupled between the third power electronic module and the fourth power electronic module; and a heat sink assembly mechanically coupled to the second power electronic module and the fourth power electronic module, wherein the heat sink assembly defines a channel configured to receive a fluid of a fluid cooling system, wherein the first DC/DC converter and the second DC/DC converter are positioned within the shared enclosure.

In another aspect, this disclosure is directed to a battery powered machine comprising: an electrical system, the electrical system comprising: an assembly for two DC/DC converters located in a shared enclosure, the assembly comprising: a first DC/DC converter including: a first power electronic module configured to receive a first DC input voltage and generate a first voltage; a second power electronic module configured to generate a second voltage; and a first transformer electrically coupled between the first power electronic module and the second power electronic module; a second DC/DC converter including: a third power electronic module configured to receive a second DC input voltage and generate a third voltage; a fourth power electronic module configured to generate a fourth voltage; and a second transformer electrically coupled between the third power electronic module and the fourth power electronic module; and a heat sink assembly mechanically coupled to the second power electronic module and the fourth power electronic module, wherein the heat sink assembly defines a channel configured to receive a fluid of a fluid cooling system, wherein the first DC/DC converter and the second DC/DC converter are positioned within the shared enclosure.

In yet another aspect, this disclosure is directed to a method of assembling two DC/DC converters in an enclosure shared by the two DC/DC converters, the method comprising: mechanically coupling a power electronic module of a first DC/DC converter to a heat sink assembly; mechanically coupling a power electronic module of a second DC/DC converter to the heat sink assembly; and positioning the first DC/DC converter and the second DC/DC converter within the enclosure shared by first DC/DC converter and the second DC/DC converter.

### BRIEF DESCRIPTION OF THE DRAWINGS

FIG. 1 is a perspective view of an example of a battery powered machine that can implement various techniques of this disclosure.

FIG. 2 is a schematic illustration of a DC/DC converter that can be used by the machine of FIG. 1.

FIG. 3 is a diagrammatic view of an example of an electric powertrain using the DC/DC converter of the present disclosure.

FIG. 4 depicts an assembly for two DC/DC converters configured to be located in a shared enclosure, in accordance with this disclosure.

FIG. 5 depicts an example of the shared heat sink assembly of FIG. 4.

FIG. 6 depicts an example of a cooling system for the first DC/DC converter and the second DC/DC converter of FIG. 4.

FIG. 7 depicts the assembly of two DC/DC converters of FIG. 4 located in a shared enclosure.

FIG. 8 is a flow diagram of an example of a method of assembling two DC/DC converters in an enclosure shared by the two DC/DC converters.

### DETAILED DESCRIPTION

In high power applications, a DC/DC converter can include large, specialized components that increase in size as power ratings are increased. Additionally, these high-power applications can include space constraints that can make it difficult to provide a DC/DC converter that has a sufficient power rating to accommodate the application.

The present inventors have recognized the need for an electrical architecture for a power dense DC/DC converter system that minimizes its footprint and that has a simplified cooling system. This disclosure describes, among other things, an assembly for two (or more) DC/DC converters located in a common enclosure, where the DC/DC converters share a heat sink assembly, such as a shared dual-sided heat sink assembly. The techniques of this disclosure efficiently package the components of the DC/DC converters within a common enclosure and simplify the cooling lines routed to those components.

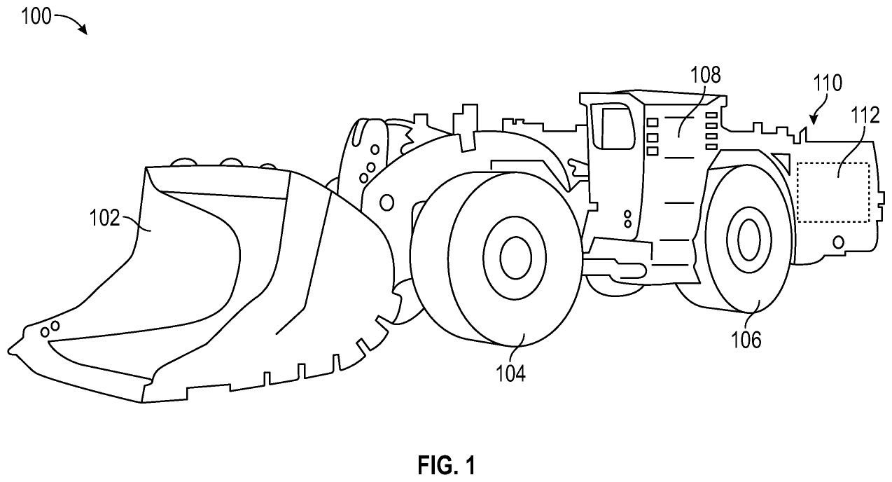

FIG. 1 is a perspective view of an example of a battery powered machine 100 that can implement various techniques of this disclosure. FIG. 1 depicts a non-limiting view of a battery powered machine 100 in the form of a load-haul-dump (LHD) vehicle, such as for mining, including a dump bucket 102, wheels 104, 106, an operator control cabin 108, and a vehicle body 110.

The battery powered machine 100, e.g., an electric mine truck, also includes an electrical architecture 112. The electrical architecture 112 can include a DC power source, including but not limited to a battery module, that can supply power to, among other things, an electric motor. The electric motor can supply rotational power to one or more systems, such as a system configured to operate various hydraulics of the dump bucket 102. The techniques of this disclosure are not limited to the LHD vehicles and are instead applicable to other industrial vehicles including, but not limited to, continuous miners, feeder breakers, roof bolters, utility vehicles for mining, underground mining loaders, underground articulated trucks, or any other vehicle used for industrial purposes, such as hauling, excavating, drilling, loading, dumping, compacting, etc. Further, the techniques of this disclosure, while especially suited to use in battery-powered vehicles, also could be used in hybrid-powered vehicles, and internal-combustion-powered vehicles.

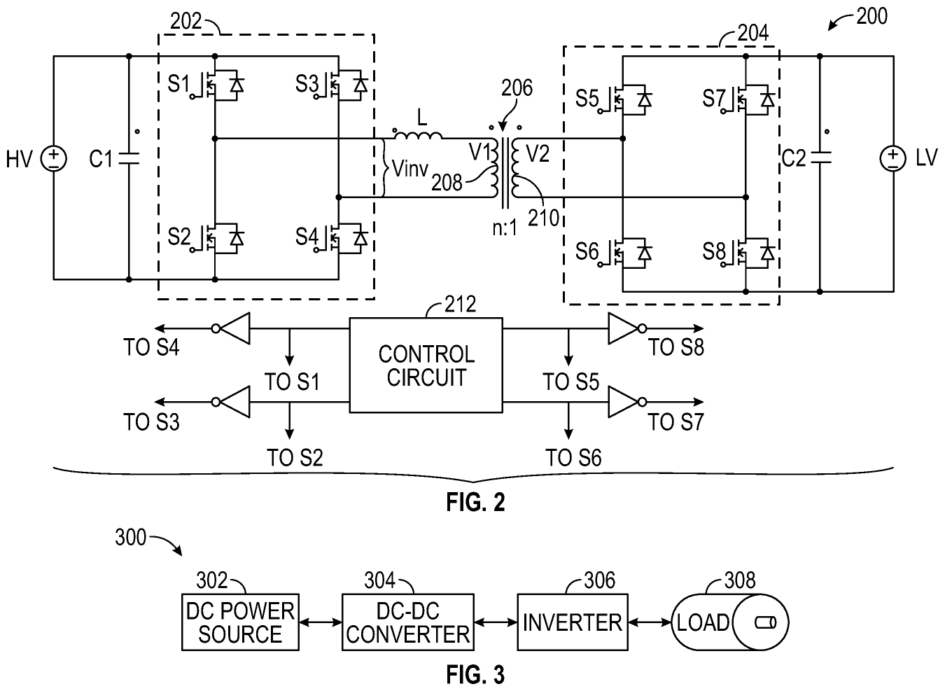

FIG. 2 is a schematic illustration of a DC/DC converter that can be used by the machine of FIG. 1. In high power applications, bridge-type bidirectional converters are common choices for use as power transfer units. A dual active full bridge converter can be used to transfer power. The dual active bridge converter (DAB) is a buck and a boost bidirectional DC/DC converter, based on two active full bridge circuits interfaced through a high frequency transformer. For example, the DC/DC converter can be a dual active bridge DC/DC converter 200. The DC/DC converter can form part of the electrical architecture 112 of FIG. 1.

In some examples, the dual active bridge DC/DC converter 200 includes a first full bridge circuit 202 that includes a plurality of electronic switches S1-S4 and a second full bridge circuit 204 that includes a plurality of electronic switches S5-S8. The dual active bridge DC converter 200 includes a transformer 206 coupled between the first full bridge circuit 202 and the second full bridge circuit 204. The transformer 206 includes a turns ratio of n:1. The dual active bridge DC converter 200 includes an inductor L coupled between the first full bridge circuit 202 and a primary winding 208 of the transformer 206.

The first full bridge circuit 202 is configured to generate a voltage V1 at the primary winding 208 of the transformer 206 and the second full bridge circuit 204 is configured to generate a voltage V2 at a secondary winding 210 of the transformer 206. A control circuit 212 is configured to, among other things, generate control signals to control operation of the switches S1-S8 so that the first full bridge circuit 202 and the second full bridge circuit 204 can generate the voltages V1, V2, respectively. The sets of switches (S1, S2), (S4, S3), (S5, S6) and (S8, S7) are complementary pairs with each switch operating at 50% duty cycle respectively. Thus, if S1 is ON then S2 will be OFF and if S1 is OFF then S2 will be ON, for example.

The first full bridge circuit 202 is coupled to a first voltage source (labeled HV) and a capacitor C1. The second full bridge circuit 204 is coupled to a second voltage source (labeled LV) and a capacitor C2. It should be noted that the first voltage source (HV) is not necessarily a higher voltage than second voltage source (labeled LV).

Electric machines are powered by batteries instead of an engine. A battery pack can include one or more battery modules, and a battery module can include one or more battery cells. The second voltage source LV can include one or more battery modules. The first voltage source HV can include a DC bus, such as coupled to an electric load, such as a motor of an electric machine, via an inverter, as shown in FIG. 3.

FIG. 3 is a diagrammatic view of an example of an electric powertrain using the DC/DC converter of the present disclosure. The powertrain 300 can be used in combination with an electric machine, such as the electric machine 100 of FIG. 1. In the examples shown, the powertrain 300 includes a DC power source 302, such as one or more battery modules that each include one or more battery cells. The DC power source 302 is coupled to a DC/DC converter 304, such as the dual active bridge DC/DC converter 200 of FIG. 2.

The DC/DC converter 304 is coupled to an inverter 306, which generates an AC voltage from the output of the DC/DC converter 304. An electrically drivable load 308, such as a motor of an electric machine, is coupled to the inverter 306.

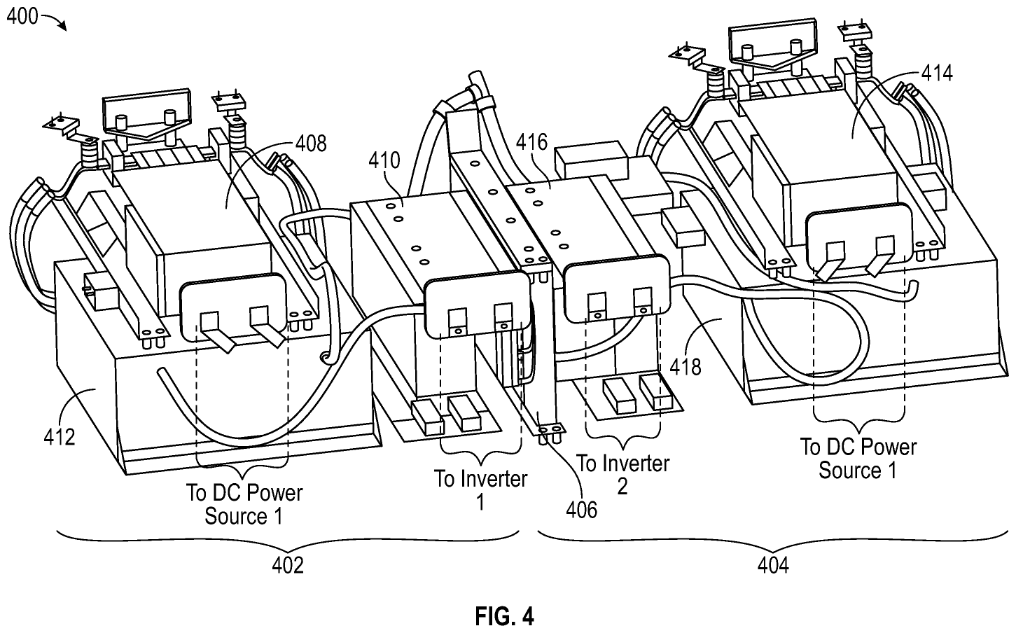

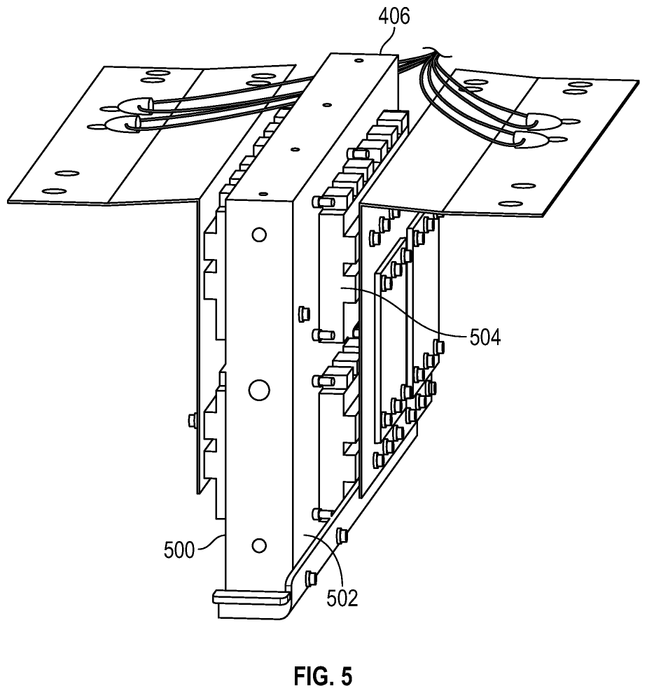

FIG. 4 depicts an assembly for two DC/DC converters configured to be located in a shared enclosure, in accordance with this disclosure. As described in more detail below, the assembly 400 includes two DC/DC converters 402, 404 that share a heat sink assembly 406 and are combined in a single enclosure. The heat sink assembly 406 is shown in more detail in FIG. 5.

In some examples, each of the first DC/DC converter 402 and the second DC/DC converter 404 can be a dual active bridge DC/DC converter, such as shown in FIG. 2. The first DC/DC converter 402 includes a first power electronic module 408, a second power electronic module 410, and a first transformer 412 electrically coupled between the first power electronic module 408 and the second power electronic module 410. The first power electronic module 408 is configured to receive a first DC input voltage and generate a first voltage. For example, the first power electronic module 408 can include components similar to those of the first full bridge circuit 202 of FIG. 2. The first power electronic module 408 can receive a voltage from an external DC power source, such as a battery module, and generate a voltage, such as the voltage V1 in FIG. 2, at the primary winding of the first transformer 412.

The second power electronic module 410 is coupled to the first transformer 412 and configured to generate a second voltage. For example, the second power electronic module 410 can include components similar to those of the second full bridge circuit 204 of FIG. 2 and can generate a voltage LV, such as coupled to the inverter 306 of FIG. 3.

The second DC/DC converter 404 is similar to the first DC/DC converter 402. The second DC/DC converter 404 includes a first power electronic module 414, a second power electronic module 416, and a first transformer 418 electrically coupled between the first power electronic module 414 and the second power electronic module 416. The first power electronic module 414 is configured to receive a first DC input voltage and generate a first voltage. For example, the first power electronic module 414 can include components similar to those of the first full bridge circuit 202 of FIG. 2. The first power electronic module 414 can receive a voltage from an external DC power source, such as a battery module, and generate a voltage, such as the voltage V1 in FIG. 2, at the primary winding of the first transformer 418.

The first DC/DC converter 402 and the second DC/DC converter 404 are independent of one another. In some examples, the first DC input voltage coupled to the first power electronic module 408 of the first DC/DC converter 402 and the first DC input voltage coupled to the first power electronic module 414 of the second DC/DC converter 402 are the same voltage and are provided by the same DC power source, such as the DC power source 302 of FIG. 3, e.g., a battery module.

Using the techniques of this disclosure, the first DC/DC converter 402 and the second DC/DC converter 404 share the heat sink assembly 406. The heat sink assembly 406 is mechanically coupled to the second power electronic module 410 of the first DC/DC converter 402 and the second power electronic module 416 of the second DC/DC converter 404. The heat sink assembly defines a channel, cavity, or other passageway configured to receive a fluid of a fluid cooling system. In some examples, the fluid can be a liquid. In other examples, the fluid can be a gas. The first DC/DC converter 402 and the second DC/DC converter 404 are positioned within a shared enclosure, as shown in FIG. 7.

FIG. 5 depicts an example of the shared heat sink assembly of FIG. 4. The second power electronic module 410 of the first DC/DC converter 402 is coupled to a first side 500 of the heat sink assembly 406 and the second power electronic module 416 of the second DC/DC converter 404 is coupled to a second side 502 of the heat sink assembly 406. In the example shown, the second side 502 is opposite the first side 500. Components 504, e.g., switches such as insulated-gate bipolar transistors (IGBTs), of the second power electronic module 416 of the second DC/DC converter 404 are shown coupled to the second side 502. Corresponding IGBTs of the second power electronic module 410 of the first DC/DC converter 402 can be provided on the first side 500.

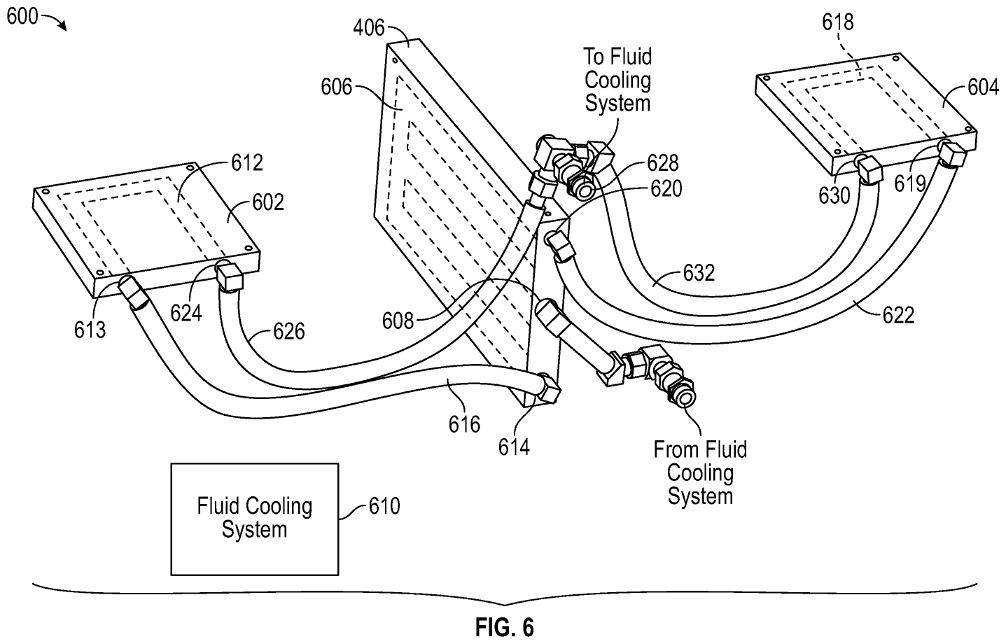

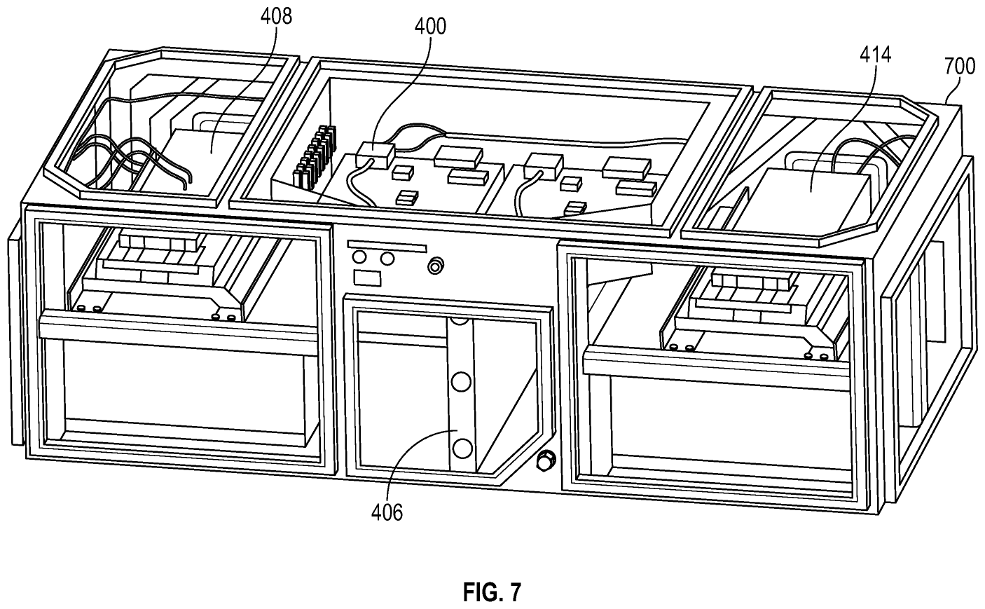

FIG. 6 depicts an example of a cooling system for the first DC/DC converter and the second DC/DC converter of FIG. 4. The cooling system 600 includes the heat sink assembly 406 of FIG. 4 as well as a heat sink assembly 602 that can be mechanically coupled to the first power electronic module 408 of the first DC/DC converter and a heat sink assembly 604 that can be mechanically coupled to the first power electronic module 414 of the second DC/DC converter of FIG. 4.

As mentioned above, the heat sink assembly 406 defines a first channel 606 or other interior passageway that is configured to receive a fluid of a fluid cooling system. The heat sink assembly 406 includes a cooling system input port 608 coupled to the first channel 606 and to the fluid cooling system 610. The cooling system input port 608 configured to receive the fluid, e.g., liquid or gas, of the fluid cooling system 610. In some examples, the heat sink assembly 406 can split the received fluid into two approximately equal portions that exit the heat sink assembly 406 at a first cooling system output port 614 and a second cooling system output port 620.

The heat sink assembly 602 defines a second channel 612 configured to receive a first portion of the fluid of the fluid cooling system 610 via an input port 613. The heat sink assembly 406 includes the first cooling system output port 614 coupled to the first channel 606 and configured to supply, via a first tube 616, the first portion of the fluid to the second channel 612.

Similarly, the heat sink assembly 604 defines a third channel 618 configured to receive a second portion of the fluid of the fluid cooling system 610 via an input port 619. The heat sink assembly 406 includes the second cooling system output port 620 coupled to the first channel 606 and configured to supply, via a second tube 622, the second portion of the fluid to the third channel 618.

The second heat sink assembly 602 includes a third cooling system output port 624 coupled to the second channel 612. The third cooling system output port 624 is coupled, via a third tube 626, to a primary cooling system output port 628. The primary cooling system output port 628 is coupled to the fluid cooling system 610 and is configured to return the fluid to the fluid cooling system 610.

The third heat sink assembly 604 includes a fourth cooling system output port 630 coupled to the third channel 618. The fourth cooling system output port 630 is coupled, via a fourth tube 632, to the primary cooling system output port 628.

FIG. 7 depicts the assembly of two DC/DC converters of FIG. 4 located in a shared enclosure. The assembly 400 of FIG. 4 is positioned within an enclosure 700 that is shared by the first DC/DC converter 402 of FIG. 4 and the second DC/DC converter 404 of FIG. 4.

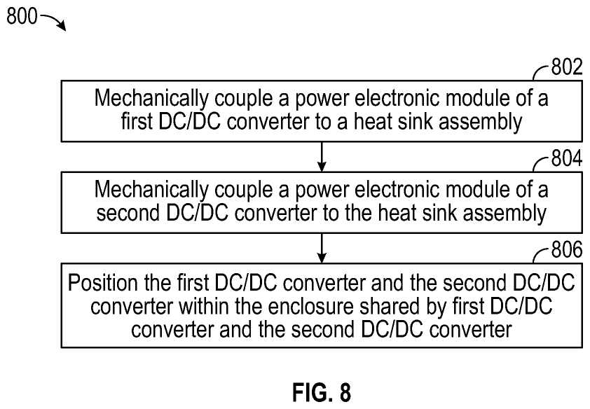

FIG. 8 is a flow diagram of an example of a method 800 of assembling two DC/DC converters in an enclosure shared by the two DC/DC converters. At block 802, the method 800 includes mechanically coupling a power electronic module of a first DC/DC converter to a heat sink assembly. For example, the power electronic module 410 of FIG. 4 can be mechanically coupled to the heat sink assembly 406 of FIG. 6.

At block 804, the method 800 includes mechanically coupling a power electronic module of a second DC/DC converter to the heat sink assembly. For example, the power electronic module 416 of FIG. 4 can be mechanically coupled to the heat sink assembly 406 of FIG. 6.

At block 806, the method 800 includes positioning the first DC/DC converter and the second DC/DC converter within the enclosure shared by first DC/DC converter and the second DC/DC converter. For example, the first DC/DC converter 402 of FIG. 4 and the second DC/DC converter 404 of FIG. 4 can be positioned within the enclosure 700 of FIG. 7.

In some examples, the method 800 includes mechanically coupling the power electronic module of the first DC/DC converter to a first side of the heat sink assembly and mechanically coupling a power electronic module of the second DC/DC converter to a second side of the heat sink assembly, wherein the second side is opposite the first side.

In some examples, the method 800 includes defining a first channel in the heat sink assembly, where the first channel is configured to receive a fluid of a fluid cooling system.

In some examples, the method 800 includes mechanically coupling the power electronic module of the first DC/DC converter to second heat sink assembly and mechanically coupling the power electronic module of the second DC/DC converter to third heat sink assembly.

In some examples, the method 800 includes defining a second channel in the second heat sink assembly, where the second channel is configured to receive a first portion of the fluid of the fluid cooling system, and defining a third channel in the third heat sink assembly, where the third channel is configured to receive a second portion of the fluid of the fluid cooling system.

### INDUSTRIAL APPLICABILITY

In high power applications, a DC/DC converter can include large, specialized components that increase in size as power ratings are increased. Additionally, these high power applications can include space constraints that can make it difficult to provide a DC/DC converter that has a sufficient power rating to accommodate the application.

The present inventors have recognized the need for an electrical architecture for a power dense DC/DC converter system that minimizes its footprint and that has a simplified cooling system. This disclosure describes, among other things, an assembly for two (or more) DC/DC converters located in a common enclosure, where the DC/DC converters share a heat sink assembly, such as a shared dual-sided heat sink assembly. The techniques of this disclosure efficiently package the components of the DC/DC converters within a common enclosure and simplify the cooling lines routed to those components.

Unless explicitly excluded, the use of the singular to describe a component, structure, or operation does not exclude the use of plural such components, structures, or operations or their equivalents. The use of the terms “a” and “an” and “the” and “at least one” or the term “one or more,” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B” or one or more of A and B”) is to be construed to mean one item selected from the listed items (A or B) or any combination of two or more of the listed items (A and B; A, A and B; A, B and B), unless otherwise indicated herein or clearly contradicted by context. Similarly, as used herein, the word “or” refers to any possible permutation of a set of items. For example, the phrase “A, B, or C” refers to at least one of A, B, C, or any combination thereof, such as any of: A; B; C; A and B; A and C; B and C; A, B, and C; or multiple of any item such as A and A; B, B, and C; A, A, B, C, and C; etc.

The above detailed description is intended to be illustrative, and not restrictive. The scope of the disclosure should, therefore, be determined with references to the appended claims, along with the full scope of equivalents to which such claims are entitled.

What is claimed is:

1. An assembly for two DC/DC converters located in a shared enclosure, the assembly comprising:
a first DC/DC converter including:
a first power electronic module configured to receive a first DC input voltage and generate a first voltage;
a second power electronic module configured to generate a second voltage; and
a first transformer electrically coupled between the first power electronic module and the second power electronic module;
a second DC/DC converter including:
a third power electronic module configured to receive a second DC input voltage and generate a third voltage;
a fourth power electronic module configured to generate a fourth voltage; and
a second transformer electrically coupled between the third power electronic module and the fourth power electronic module; and
a heat sink assembly mechanically coupled to the second power electronic module and the fourth power electronic module, wherein the heat sink assembly defines a channel configured to receive a fluid of a fluid cooling system,
wherein the first DC/DC converter and the second DC/DC converter are positioned within the shared enclosure.

2. The assembly of claim 1, wherein the first DC input voltage and the second DC input voltage are the same voltage and provided by a DC power source.

3. The assembly of claim 1, wherein the second power electronic module is coupled to a first side of the heat sink assembly and the fourth power electronic module is coupled to a second side of the heat sink assembly, wherein the second side is opposite the first side.

4. The assembly of claim 1, wherein the heat sink assembly is a first heat sink assembly, and wherein the channel is a first channel, the assembly further comprising:
a second heat sink assembly coupled to the first power electronic module, wherein the second heat sink assembly defines a second channel configured to receive a first portion of the fluid of the fluid cooling system; and
a third heat sink assembly coupled to the second power electronic module, wherein the third heat sink assembly defines a third channel configured to receive a second portion of the fluid of the fluid cooling system.

5. The assembly of claim 4, wherein the first heat sink assembly includes:
a cooling system input port coupled to the first channel and to the fluid cooling system, the cooling system input port configured to receive the fluid of the fluid cooling system;
a first cooling system output port coupled to the first channel and configured to supply, via a first tube, the first portion of the fluid to the second channel; and
a second cooling system output port coupled to the first channel and configured to supply, via a second tube, the second portion of the fluid to the third channel.

6. The assembly of claim 5, further comprising:
a primary cooling system output port coupled to the fluid cooling system, the primary cooling system output port configured to return the fluid to the fluid cooling system,
wherein the second heat sink assembly includes a third cooling system output port coupled to the second channel, wherein the third cooling system output port is coupled, via a third tube, to the primary cooling system output port, and
wherein the third heat sink assembly includes a fourth cooling system output port coupled to the third channel, wherein the fourth cooling system output port is coupled, via a fourth tube, to the primary cooling system output port.

7. The assembly of claim 1, wherein at least one of the first DC/DC converter and the second DC/DC converter is a dual active bridge DC/DC converter.

8. A battery powered machine comprising:
an electrical system, the electrical system comprising:
an assembly for two DC/DC converters located in a shared enclosure, the assembly comprising:
a first DC/DC converter including:
a first power electronic module configured to receive a first DC input voltage and generate a first voltage;
a second power electronic module configured to generate a second voltage; and
a first transformer electrically coupled between the first power electronic module and the second power electronic module;
a second DC/DC converter including:
a third power electronic module configured to receive a second DC input voltage and generate a third voltage;
a fourth power electronic module configured to generate a fourth voltage; and
a second transformer electrically coupled between the third power electronic module and the fourth power electronic module; and
a heat sink assembly mechanically coupled to the second power electronic module and the fourth power electronic module, wherein the heat sink assembly defines a channel configured to receive a fluid of a fluid cooling system,
wherein the first DC/DC converter and the second DC/DC converter are positioned within the shared enclosure.

9. The battery powered machine of claim 8, wherein the first DC input voltage and the second DC input voltage are the same voltage and provided by a DC power source.

10. The battery powered machine of claim 8, wherein the second power electronic module is coupled to a first side of the heat sink assembly and the fourth power electronic module is coupled to a second side of the heat sink assembly, wherein the second side is opposite the first side.

11. The battery powered machine of claim 8, wherein the heat sink assembly is a first heat sink assembly, and wherein the channel is a first channel, the assembly further comprising:
a second heat sink assembly coupled to the first power electronic module, wherein the second heat sink assembly defines a second channel configured to receive a first portion of the fluid of the fluid cooling system; and
a third heat sink assembly coupled to the second power electronic module, wherein the third heat sink assembly defines a third channel configured to receive a second portion of the fluid of the fluid cooling system.

12. The battery powered machine of claim 11, wherein the first heat sink assembly includes:
a cooling system input port coupled to the first channel and to the fluid cooling system, the cooling system input port configured to receive the fluid of the fluid cooling system;
a first cooling system output port coupled to the first channel and configured to supply, via a first tube, the first portion of the fluid to the second channel; and
a second cooling system output port coupled to the first channel and configured to supply, via a second tube, the second portion of the fluid to the third channel.

13. The battery powered machine of claim 12, further comprising:
a primary cooling system output port coupled to the fluid cooling system, the primary cooling system output port configured to return the fluid to the fluid cooling system,
wherein the second heat sink assembly includes a third cooling system output port coupled to the second channel, wherein the third cooling system output port is coupled, via a third tube, to the primary cooling system output port, and
wherein the third heat sink assembly includes a fourth cooling system output port coupled to the third channel, wherein the fourth cooling system output port is coupled, via a fourth tube, to the primary cooling system output port.

14. The battery powered machine of claim 8, wherein at least one of the first DC/DC converter and the second DC/DC converter is a dual active bridge DC/DC converter.

15. The battery powered machine of claim 8, wherein the battery powered machine is an electric mine truck.

16. A method of assembling two DC/DC converters in an enclosure shared by the two DC/DC converters, the method comprising:
mechanically coupling a power electronic module of a first DC/DC converter to a heat sink assembly;
mechanically coupling a power electronic module of a second DC/DC converter to the heat sink assembly; and
positioning the first DC/DC converter and the second DC/DC converter within the enclosure shared by first DC/DC converter and the second DC/DC converter.

17. The method of claim 16,
wherein mechanically coupling a power electronic module of a first DC/DC converter to a heat sink assembly includes:
mechanically coupling the power electronic module of the first DC/DC converter to a first side of the heat sink assembly, and
wherein mechanically coupling a power electronic module of a second DC/DC converter to the heat sink assembly includes:
mechanically coupling a power electronic module of the second DC/DC converter to a second side of the heat sink assembly, wherein the second side is opposite the first side.

18. The method of claim 16, wherein the heat sink assembly is a first heat sink assembly, the method further comprising:
defining a channel in the first heat sink assembly, wherein the channel is configured to receive a fluid of a fluid cooling system.

19. The method of claim 18, further comprising:
mechanically coupling the power electronic module of the first DC/DC converter to a second heat sink assembly; and
mechanically coupling the power electronic module of the second DC/DC converter to a third heat sink assembly.

20. The method of claim 19, wherein the channel is a first channel, the method further comprising:
defining a second channel in the second heat sink assembly, wherein the second channel is configured to receive a first portion of the fluid of the fluid cooling system; and
defining a third channel in the third heat sink assembly, wherein the third channel is configured to receive a second portion of the fluid of the fluid cooling system.
